(19) United States
(12) Patent Application Publication
(10) Pub. No.: US 2015/0362578 A1
(43) Pub. Date: Dec. 17, 2015

(54) Magnetic Resonance Imaging

(71) Applicants: Stephan Biber, Erlangen (DE); Daniel Niederlöhner, Erlangen (DE); Andreas Schmidt, Erlangen (DE); Markus Vester, Nurnberg (DE)

(72) Inventors: Stephan Biber, Erlangen (DE); Daniel Niederlöhner, Erlangen (DE); Andreas Schmidt, Erlangen (DE); Markus Vester, Nurnberg (DE)

(21) Appl. No.: 14/738,884

(22) Filed: Jun. 13, 2015

(30) Foreign Application Priority Data
Jun. 13, 2014 (DE) 102014211354.7

(51) Int. Cl. G01R 33/565; G01R 33/3875; G01R 33/48

(52) U.S. Cl. CPC G01R 33/56563; G01R 33/4828; G01R 33/3875

(57) ABSTRACT

In order to enable efficient calculation of shim settings for a magnetic resonance imaging system, a method for magnetic resonance imaging of an object under investigation using a magnetic resonance device is provided. The method includes acquiring first magnetic resonance image data of the object under investigation using the magnetic resonance device. The method also includes segmenting the first magnetic resonance image data into at least two material classes, calculating a B0 map based on the segmented first magnetic resonance image data and based on susceptibility values of the at least two material classes, and calculating shim settings based on the calculated B0 map. The method also includes acquiring second magnetic resonance image data of the object under investigation using the magnetic resonance device. The acquisition of the second magnetic resonance image data is undertaken using the calculated shim settings.

This application claims the benefit of DE 10 2014 211 354.7, filed on Jun. 13, 2014, which is hereby incorporated by reference in its entirety.

### BACKGROUND

The present embodiments relate to a method for magnetic resonance imaging and a magnetic resonance device.

In a magnetic resonance device (e.g., a “magnetic resonance tomography system”), the body of the subject to be examined (e.g., of a patient) is typically exposed to a relatively strong magnetic field of, for example, 1.5 or 3 or 7 Tesla, with the aid of a main magnet. In addition, gradient pulses are applied with the aid of a gradient coil unit. Using a high frequency antenna unit, using suitable antenna devices, high frequency pulses (e.g., excitation pulses) are then transmitted, which has the effect that the nuclear spins of particular atoms excited into resonance by these high frequency pulses are tilted through a defined flip angle relative to the magnetic field lines of the main magnetic field. On relaxation of the nuclear spin, high frequency signals known as “magnetic resonance signals” are emitted and are received by suitable high frequency antennae and then further processed. From the raw data thereby acquired, the desired image data may ultimately be reconstructed.

For a particular measurement, a particular magnetic resonance sequence (e.g., a pulse sequence) that consists of a sequence of high frequency pulses (e.g., excitation pulses and refocusing pulses), as well as gradient pulses to be transmitted suitably coordinated therewith on various gradient axes along different spatial directions, is herein to be transmitted. Temporally adapted thereto, readout windows are set, and magnetic resonance signals are detected.

In magnetic resonance imaging using a magnetic resonance device, the homogeneity of a main magnetic field in an examination volume is of great significance. Even small deviations in the homogeneity may lead to large deviations in a frequency distribution of the nuclear spin so that qualitatively inferior magnetic resonance image data is recorded.

In order to improve the homogeneity in the examination volume, shim devices are known. Once a magnetic resonance device has been installed at a designated location, fields present in the surroundings may restrict the existing homogeneity of the main magnetic field (e.g., around an isocenter of the magnetic resonance device). Therefore, on installation and commissioning of a magnetic resonance device, often in conjunction with measurements, the shim device is adjusted such that the greatest possible homogeneity is created. In this way, during the installation and commissioning of the magnetic resonance device, basic shim settings are calculated.

However, a further source of inhomogeneity is the object under investigation itself. If, for example, a person under investigation is introduced into the magnetic resonance device, the material of the body again disrupts the homogeneity, due to the magnetic susceptibility thereof. In order to counter this problem, it is known to use an adjustable shim unit. For example, for this purpose, electrical shim coils that are driven with different shim currents for generating compensating magnetic fields in order to improve the homogeneity are known.

In order to shim these disturbances by the object under investigation, it is usual initially when controlling the shim unit using the basic shim settings obtained during the installation and commissioning of the magnetic resonance installation, using the magnetic resonance device itself, to undertake a measurement of a field distribution (e.g., a “B0 map”) when the person under investigation has been introduced into a patient receiving region of the magnetic resonance device. Thereafter, starting from the basic shim settings, optimized shim settings are determined by a shim control unit, taking account of the measured field distribution. Making use of the optimized shim settings, the shim unit is then controlled in order to obtain the optimum possible homogeneity.

In conventional methods, the B0 map that is needed for calculating the shim settings is typically determined in a separate measurement. In this separate measurement, phase differences and/or frequency differences are typically measured to generate the B0 map. This separate measurement of the B0 map in conventional methods has the disadvantage that the separate measurement is associated with an increase in the measuring time. It is also a contributing factor therein that, after a change in a table position of a patient positioning device of the magnetic resonance device, the B0 map must possibly be determined anew in a further separate measurement. The B0 map determined according to a conventional method in a separate measurement may contain signal aliasing in the phase encoding direction and may thus lead to problems in the correct calculation of the shim settings based on the B0 map.

From the publication by Salomir et al., “A Fast Calculation Method for Magnetic Field Inhomogeneity due to an Arbitrary Distribution of Bulk Susceptibility,” Concepts in Magnetic Resonance Part B (Magnetic Resonance Engineering), Vol. 19B(1) 26-34 (2003), it is known to calculate a B0 map from a distribution of susceptibility values.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, an efficient calculation of shim settings for magnetic resonance imaging is provided.

One or more of the present embodiments are based on a method for magnetic resonance imaging of an object under investigation using a magnetic resonance device. The method includes acquiring first magnetic resonance image data of the object under investigation using the magnetic resonance device. The method also includes segmenting the first magnetic resonance image data into at least two material classes, calculating a B0 map based on the segmented first magnetic resonance image data and based on susceptibility values of the at least two material classes, and calculating shim settings based on the calculated B0 map. The method includes acquiring second magnetic resonance image data of the object under investigation using the magnetic resonance device. The acquisition of the second magnetic resonance image data is undertaken using the calculated shim settings.

The object under investigation may be a patient, a training person, or a phantom. Based on the second magnetic resonance image data, for example, magnetic resonance images are generated by a computer unit of the magnetic resonance device. The magnetic resonance images may be output on a display unit of the magnetic resonance device and/or stored in a database.

Shim settings may include settings for controlling a shim unit of the magnetic resonance device. For example, the shim settings may stipulate a, possibly time-dependent, distribution of the currents in the shim coils of the shim unit. The calculation of the shim settings may thus include a calculation of shim currents. Based on shim settings, a frequency-adjustment may also be carried out before an acquisition of the second magnetic resonance image data. The different shim settings may be calculated before the acquisition of the second magnetic resonance image data.

A B0 map represents, for example, a field distribution of a main magnetic field of the magnetic resonance device. The B0 map is then, for example, proportional to the main magnetic field (e.g., B0 field) of the magnetic resonance device. The B0 map may thus serve to identify inhomogeneities in the main magnetic field (e.g., if the object under investigation is positioned in the magnetic resonance device). The calculation of the shim settings may take place based on the calculated B0 map such that the inhomogeneities of the main magnetic field are compensated for by the shim settings used during the acquisition of the second magnetic resonance image data.

According to the proposed procedure, the B0 map that is used for calculating the shim settings is calculated based on first magnetic resonance image data. The first magnetic resonance image data is acquired from the object under investigation, for example, before the calculation of the B0 map, by the magnetic resonance device. The first magnetic resonance image data may be obtained, for example, during a magnetic resonance survey view (e.g., localizer) that is typically carried out at the start of a scan in order to plan the subsequent diagnostic recordings. In one embodiment, the first magnetic resonance image data is formed from already recorded diagnostic image data of the object under investigation. In one embodiment, the first magnetic resonance image data is acquired during a pre-scan measurement, for example, for normalizing image data. Other possibilities that a person skilled in the art would consider useful for acquiring the first magnetic resonance image data may also be provided. The first magnetic resonance image data is, for example, not recorded during a separate measurement of a B0 map. Rather, according to the proposed procedure, the separate direct recording of a B0 map is advantageously to be dispensed with. For this reason, the first magnetic resonance image data possibly already recorded during the image data recording process for the object under investigation may be used to generate the B0 map.

In order to calculate the B0 map, the first magnetic resonance image data is segmented into at least two material classes. The at least two material classes include, for example, materials with different physical properties (e.g., different susceptibility values). If the first magnetic resonance image data is segmented into at least two material classes, the respective susceptibility value may be assigned to the at least two material classes. The respective susceptibility values of the material classes may be stored, for example, in a database. The first magnetic resonance image data may thus be converted into a susceptibility map that represents a spatially resolved three-dimensional distribution of susceptibility values of the object under investigation. This susceptibility map may then serve as the basis for calculating the B0 map. A method for generating a B0 map from a susceptibility map is known from the publication “A Fast Calculation Method for Magnetic Field Inhomogeneity due to an Arbitrary Distribution of Bulk Susceptibility” by Salomir et al.

Based on the B0 map generated and making use of a method known to a person skilled in the art, shim settings may be calculated. The calculation of the shim settings may include, for example, a calculation of shim currents for individual shim coils of the shim unit. The shim settings are then advantageously adapted to the object under investigation from which the first magnetic resonance image data has been recorded. Thus, for the acquisition of the second magnetic resonance image data of the object under investigation, shim settings that lead to a particularly high level of homogeneity of the main magnetic field and thus to a high level of image quality of the second magnetic resonance image data may be used. The fact that the calculated shim settings are set during the acquisition of the second magnetic resonance image data provides, for example, that during the acquisition of the second magnetic resonance image data, shim currents that are stipulated by the calculated shim settings flow through the shim coils of a shim unit of the magnetic resonance device.

The procedure proposed offers a particularly robust and efficient method for calculating the B0 map that is used for calculating the shim settings for acquiring second magnetic resonance image data. A separate measurement of the B0 map according to a conventional method may be dispensed with. Rather, the B0 map may be obtained directly from previously recorded first magnetic resonance image data. In this way, measuring time is saved, leading to an increase in the efficiency of operational procedures in a medical center and to increased patient comfort. A B0 map obtained in this way may also have fewer image artifacts than a B0 map measured during a separate scan. The complexity of the overall procedure for calculating the shim settings is also reduced.

One embodiment provides that a first of the at least two material classes is air and a second of the at least two material classes is tissue of the object under investigation. The magnetic resonance image data may also be segmented into exactly two material classes. Then, advantageously, the first of the two material classes is air and the second of the two material classes is tissue. A further distinction of the tissue types may then be dispensed with. Underlying this procedure is the consideration that typically, a particularly large susceptibility difference exists between tissue and air. The susceptibility difference between two different tissue classes (e.g., fat tissue and bone) is typically smaller than the susceptibility difference between air and tissue. Thus, even based on a segmentation of the first magnetic resonance image data into air and tissue, a B0 map that is sufficient for the calculation of shim settings in many applications may be created. A segmentation of this type into air and tissue is also advantageously very robust and saves computation time. At the same time, for a segmentation into air and tissue, a plurality of first magnetic resonance image data may be used. Then, for example, the contours of the object under investigation may be determined from the first magnetic resonance image data. Alternatively or additionally, air-filled regions in a body of the object under investigation may be determined in the first magnetic resonance image data. Air-filled regions of this type may be present, for example, in a lung region, a neck/throat region or in a paranasal sinus region of the object under investigation. Segmentation into tissue and air may also typically be carried out with relatively little effort, and robustly.

One embodiment provides that the at least two material classes include at least two different tissue classes. The different tissue classes may include, for example, water, fat, bone, etc. One tissue class of the at least two different tissue classes may also be formed by an artificial implant and/or a foreign body in the object under investigation. Through the subdivision of the object under investigation into different tissue classes, a more exact susceptibility map, and therefore shim settings that are more exactly matched to the object under investigation, may be calculated. The at least two material classes include, in addition to the at least two different tissue classes, air, for example, as a material class.

One embodiment provides that the acquisition of the first magnetic resonance image data takes place from a first recording region and the acquisition of the second magnetic resonance image data takes place from a second recording region. The second recording region is a partial region of the first recording region. Thus, the first recording region may be larger than the second recording region. The first magnetic resonance image data, which serves as the basis for generating the shim settings for the second magnetic resonance image data, therefore may represent a larger region of the object under investigation than the second magnetic resonance image data. This is advantageous, since distortions of the main magnetic field may also have effects at remote sites. Thus, an inhomogeneity of susceptibilities in a shoulder region of the object under investigation may have an effect on the main magnetic field and thus on an image quality during a heart examination. The enlargement of the recording region of the first magnetic resonance image data relative to the second magnetic resonance image data takes account of this fact since susceptibilities that lie outside the second magnetic resonance image data may thus also be taken into account in the calculation of the shim settings for the second magnetic resonance image data. In this way, the quality of the calculated B0 map may be improved, and the image quality of the second magnetic resonance image data may be increased. Alternatively, or in addition, a model of the object under investigation may also be generated based on the first magnetic resonance image data, and for the calculation of the B0 map, an anatomy of the object under investigation based on the model may be extrapolated beyond the limits of the first magnetic resonance image data. The contours of the object under investigation may be of particular interest herein. Thus, the generation of the B0 map may be based on a still larger field of view.

Another embodiment provides that the acquisition of the first magnetic resonance image data takes place during a movement of a patient table of the magnetic resonance device. A recording technique of this type is known as “move-during-scan” recording or “continuous-table-motion” recording. In this way, the first magnetic resonance image data may be recorded in a particularly time-saving manner. By the movement of the patient table, a very large part of the object under investigation may also be recorded in the shortest possible time. This may contribute to the first magnetic resonance image data having a significantly larger recording region than the second magnetic resonance image data.

Another embodiment provides that before the acquisition of the second magnetic resonance image data, first scan data is acquired by at least one further sensor different from the magnetic resonance device. The calculation of the B0 map includes use of the first scan data. A further such sensor may be an optical camera (e.g., a 3-D camera), a laser sensor, an ultrasonic sensor an ECG device, etc. Other further sensors that a person skilled in the art would consider useful may also be provided. The first scan data acquired by the further sensor may advantageously serve for estimating outer and inner contours of the object under investigation and/or a volume of the object under investigation. Thus, based on the first scan data, segmentation of the first magnetic resonance image data in air and tissue may advantageously be supported, for example, if the first magnetic resonance image data does not include the whole volume of the object under investigation. In this way, the quality of the calculated B0 map may be further improved.

Another embodiment provides that, following the acquisition of the second magnetic resonance image data, second scan data is acquired by the further sensor, an adapted B0 map based on the second scan data and the calculated B0 map is determined, adapted shim settings are calculated based on the adapted B0 map, and third magnetic resonance image data is acquired from the object under investigation using the magnetic resonance device. The acquisition of the third magnetic resonance image data takes place by using the adapted shim settings. A procedure of this type advantageously enables taking account of a movement of the object under investigation between the acquisition of the second magnetic resonance image data and the third magnetic resonance image data. The movement of the object under investigation may herein be detected by the second scan data acquired with the further sensor. Thus, for example, a breathing movement of the object under investigation between the second magnetic resonance image data and the third magnetic resonance image data may be taken into account during the calculation of the B0 map. Arbitrary movements of the limbs of the object under investigation may also be taken into account. Using an ECG device, heart phases of the object under investigation may also be determined, which enables a heart movement of the object under investigation to be taken into account. The second magnetic resonance image data and the third magnetic resonance image data may be recorded during a magnetic resonance scan, for example, in different sections of a magnetic resonance sequence. In one embodiment, the second magnetic resonance image data and the third magnetic resonance image data are recorded with different magnetic resonance sequences. The adaptation of the B0 map to the movement of the object under investigation enables adaptation of the shim settings to the movement of the object under investigation. Thus, during an examination of the object under investigation, dynamic shim settings may be changed.

One embodiment provides that, based on the first scan data, a model that describes contours of the object under investigation is determined, and the calculation of the B0 map includes use of the model. The fact that the model is used during the calculation of the B0 map provides, for example, that the model is used as an input parameter in the calculation of the B0 map. The model may stipulate initial parameters for the calculation of the B0 map. The model may describe, for example, which spatial points lie within and outside the object under investigation Inner contours of the object under investigation may also be described by the model, and these enable, for example, a delimiting of tissue and air-filled regions in the object under investigation. Based on the model, therefore, a segmentation of the object under investigation into air and tissue may be supported.

One embodiment provides that based on the second scan data, the model is adapted and the determination of the adapted B0 map includes use of the adapted model. The model is herein advantageously used as a movement model. Thus, based on the second scan data, the original model of the contours of the object under investigation is deformed. In this way, for the adapted B0 map, a changed segmentation into air and tissue based on the adapted model of the object under investigation may take place. Thus, the movement of the object under investigation may be taken into account particularly simply on creation of the B0 map.

One embodiment provides that inhomogeneities of a main magnetic field of the magnetic resonance device, which are independent of the object under investigation, are taken into account in the calculation of the B0 map Inhomogeneities of this type in the main magnetic field are present, for example, in an edge region of the main magnetic field. In this edge region, the homogeneity of the main magnetic field typically falls off relatively rapidly. The inhomogeneities of the main magnetic field may be inherent properties of the main magnet of the magnetic resonance device. Alternatively or additionally, such inhomogeneities may also be caused by components of the magnetic resonance device, such as the patient table. It is advantageous for an improvement of the quality of the shim settings to take account of inhomogeneities of the main magnetic field that are independent of the object under investigation being investigated with the magnetic resonance device. It is herein difficult to determine such inhomogeneities of the main magnetic field using the first magnetic resonance image data. It is therefore useful, when calculating the B0 map, to use additional information concerning the inhomogeneities of the main magnetic field that are independent of the object under investigation. For this purpose, before the acquisition of the second magnetic resonance image data, a calibration scan is carried out by the magnetic resonance device. During this calibration, magnetic resonance image data is acquired. The inhomogeneities of the main magnetic field of the magnetic resonance device that are independent of the object under investigation may then be determined by the calibration magnetic resonance image data. These “apparatus-related” inhomogeneities may then be additively overlaid on the inhomogeneities caused by the tissue distribution of the object under investigation. The calculation of the B0 map may also be further accelerated since underlying assumptions concerning the inhomogeneities of the main magnetic field may already be taken into account in the calculation of the B0 map. In specific application cases, a calculated B0 map may be modified before the calculation of the shim settings, taking account of the inhomogeneities of the main magnetic field of the magnetic resonance device that are independent of the object under investigation, and the calculation of the shim settings may be undertaken based on the modified B0 map.

One or more of the present embodiments relate to a magnetic resonance device with an image data acquisition unit, a shim unit, a computer unit and a shim control unit. The magnetic resonance device is configured to carry out a method according to one or more of the present embodiments.

The magnetic resonance device is therefore configured for carrying out a method for magnetic resonance imaging of an object under investigation. The image data acquisition unit is configured for acquiring first magnetic resonance image data of the object under investigation. The computer unit (e.g., a segmentation unit of the computer unit) is configured for segmenting the first magnetic resonance image data into at least two material classes. The computer unit (e.g., a calculating unit of the computer unit) is configured for calculating a B0 map based on the segmented first magnetic resonance image data and based on susceptibility values of the at least two material classes. The shim control unit is configured for calculating shim settings based on the calculated B0 map. The image data acquisition unit is configured for acquiring second magnetic resonance image data of the object under investigation using the magnetic resonance device. The acquisition of the second magnetic resonance image data takes place using the calculated shim settings. The shim unit is controlled by the shim control unit.

The magnetic resonance device may have further control components for carrying out a method according to one or more of the present embodiments. In a storage unit of the computer unit and/or the control unit, computer programs and other software may be stored. Using the computer programs and the other software, a processor of the computer unit and/or the control unit automatically controls and/or carries out the sequence of a method according to one or more of the present embodiments.

The advantages of the magnetic resonance device according to one or more of the present embodiments substantially correspond to the advantages of the method according to one or more of the present embodiments, as described in detail above. Features, advantages or alternative embodiments mentioned herein are also to be transferred similarly to the other subject matter, and vice versa. In other words, the present subject matter may also be further developed with the features disclosed in conjunction with a method. The corresponding functional features of the method are configured by suitable modules as contained herein, including, for example, hardware modules.

### BRIEF DESCRIPTION OF THE DRAWINGS

FIG. 1 shows one embodiment of a magnetic resonance device;

FIG. 2 is a flow diagram of a first embodiment of a method;

FIG. 3 is a flow diagram of a second embodiment of a method; and

FIG. 4 is a flow diagram of a third embodiment of a method.

### DETAILED DESCRIPTION

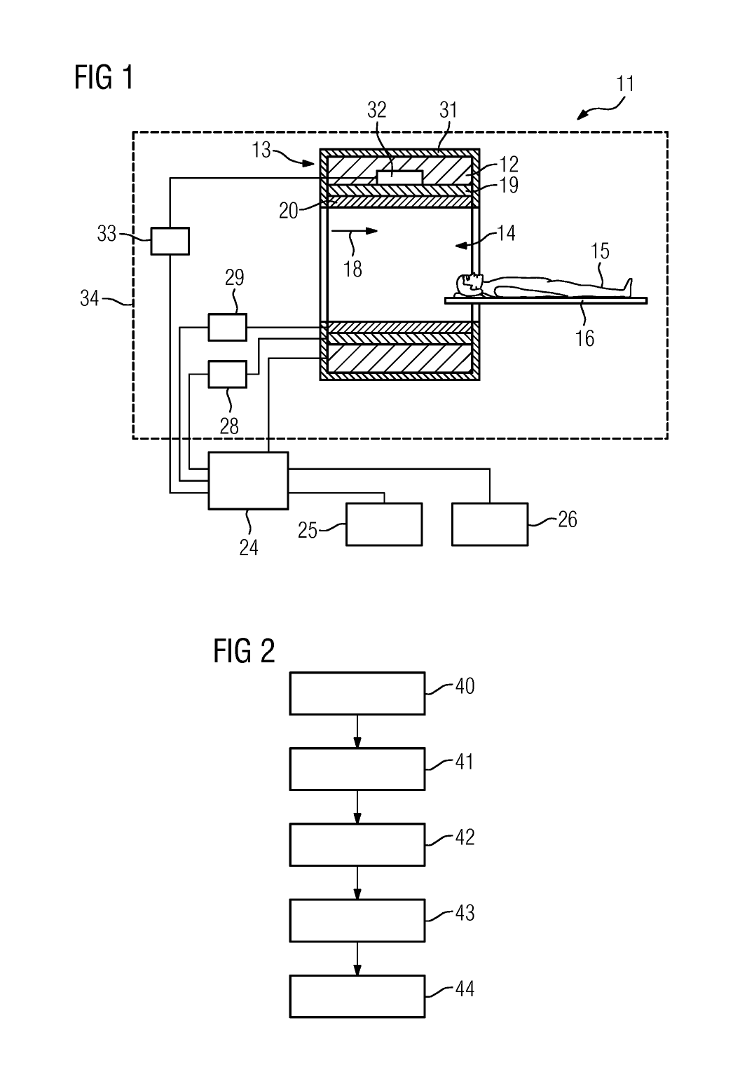

FIG. 1 shows one embodiment of a magnetic resonance device 11 in a schematic form. The magnetic resonance device 11 includes a detector unit having a magnet unit 13 with a main magnet 17 for generating a strong and, for example, constant main magnetic field 18. The magnetic resonance device 11 also includes a cylindrical patient receiving region 14 for accommodating an object under investigation 15 (e.g., a patient 15). The patient receiving region 14 is cylindrically enclosed in a peripheral direction by the magnet unit 13. The patient 15 may be pushed by a patient support apparatus 16 of the magnetic resonance device 11 into the patient receiving region 14. For this purpose, the patient support apparatus 16 has a patient table that is arranged movable within the magnetic resonance device 11. The magnet unit 13 is screened toward the outside by a housing covering 31 of the magnetic resonance device.

The magnet unit 13 also includes a gradient coil unit 19 for generating magnetic field gradients that are used for position encoding during imaging. The gradient coil unit 19 is controlled by a gradient control unit 28. The magnet unit 13 also includes a high frequency antenna unit 20 that, in the case shown, is configured as a body coil firmly integrated into the magnetic resonance device 10, and a high frequency antenna control unit 29 for excitation of a polarization that comes about in the main magnetic field 18 generated by the main magnet 17. The high frequency antenna unit 20 is controlled by the high frequency antenna control unit 29 and radiates high frequency magnetic resonance sequences into an examination space that is substantially formed by the patient receiving region 14. The high frequency antenna unit 20 is also configured for receiving magnetic resonance signals (e.g., from the patient 15).

For controlling the main magnet 17, the gradient control unit 28, and the high frequency antenna control unit 29, the magnetic resonance device 11 includes a computer unit 24. The computer unit 24 controls the magnetic resonance device 11 (e.g., the execution of a predetermined imaging gradient echo sequence) centrally. Control information such as, for example, imaging parameters and reconstructed magnetic resonance images may be displayed for a user on a display unit 25 (e.g., on at least one monitor of the magnetic resonance device 11). In addition, the magnetic resonance device 11 includes an input unit 26 by which information and/or parameters may be input by a user during a scanning procedure. The computer unit 24 may include the gradient control unit 28, the high frequency antenna control unit 29, the display unit 25, the input unit 26, or any combination thereof.

The magnetic resonance device 11 also includes an image data acquisition unit 34. In the present case, the image data acquisition unit 34 is formed by the magnet unit 13 together with the high frequency antenna control unit 29 and the gradient control unit 28. The magnetic resonance device 11 also includes a shim unit 32 and a shim control unit 33 for controlling the shim unit 32. The shim control unit 33 is connected to the computer unit 24 for the purpose of a data exchange. The shim control unit 33 may also be a part of the computer unit 24. The shim unit 32 includes, for example, shim coils. The shim coils may be formed by global shim coils that are arranged in the magnet unit 13 and/or by local shim coils that are arranged in the patient receiving region 14. The current that flows through the shim coils of the shim unit 32 may be adjusted by the shim control unit 33 by shim adjustments. Thus, the magnetic resonance device 11 is configured, together with the computer unit 24, the shim unit 32, the image data acquisition unit 34, and the shim control unit 33, to carry out a method according to one or more of the present embodiments.

The magnetic resonance device 11 disclosed may include further components that magnetic resonance devices 11 typically include. A general mode of operation of a magnetic resonance device 11 is also known to a person skilled in the art, so that a detailed description of the further components is not included.

FIG. 2 shows a flow diagram of a first embodiment of a method for magnetic resonance imaging of an object under investigation 15 using a magnetic resonance device 11.

In a first method act 40, first magnetic resonance image data of the object under investigation 15 is acquired by an image data acquisition unit 34 of the magnetic resonance device 11. This may take place, for example, during recording of a three-dimensional scout view at the start of an investigation of the object under investigation 15. In act 41, the first magnetic resonance image data is segmented by a segmenting unit (not shown) of the computer unit 24 into at least two material classes. In act 42, a calculating unit (not shown) of the computer unit 24 calculates a B0 map based on the segmented first magnetic resonance image data and based on susceptibility values of the at least two material classes. In a further act 43, shim settings are calculated by the shim control unit 33 based on the calculated B0 map. In method act 44, acquisition of second magnetic resonance image data of the object under investigation by the image data acquisition unit 34 takes place. During the acquisition of the second magnetic resonance image data, the shim unit 32 is controlled by the shim control unit 33 using the calculated shim settings. The second magnetic resonance image data may subsequently be displayed on the display unit 25 of the magnetic resonance device 11 and/or stored in a database.

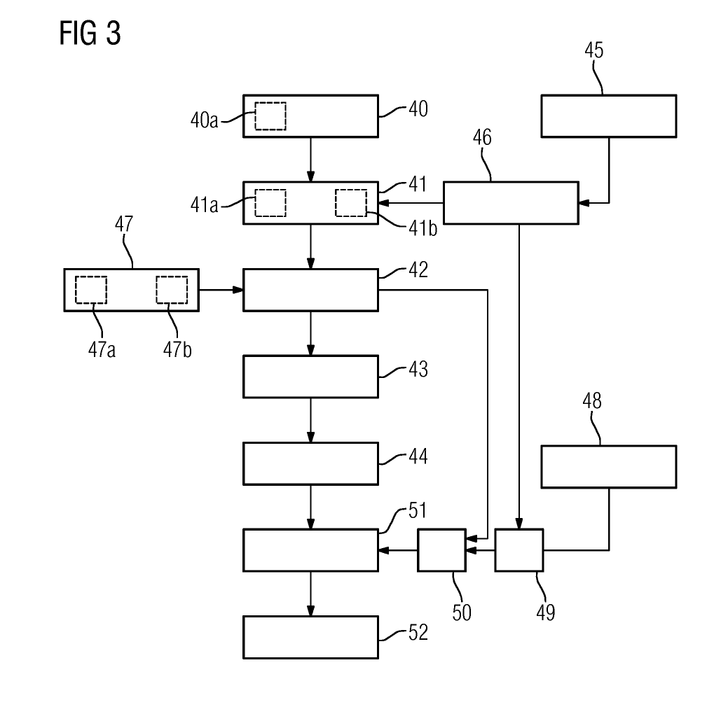

FIG. 3 shows a flow diagram of a second embodiment of a method.

The following description is essentially restricted to the differences from the exemplary embodiment in FIG. 2, where, with regard to method acts that remain the same, reference is made to the description of the exemplary embodiment in FIG. 2. Method acts that are substantially the same are essentially identified with the same reference signs.

The second embodiment of the method shown in FIG. 3 essentially includes the method acts 40, 41, 42, 43, 44 of the first embodiment of the method, as shown in FIG. 2. The second embodiment of the method shown in FIG. 3 also includes further method acts and sub-acts. Also conceivable is an alternative method sequence to that of FIG. 3 that has only part of the additional method acts and/or sub-acts09 represented in FIG. 2. An alternative method sequence to that of FIG. 3 may also have additional method acts and/or sub-acts.

The acquisition of the first magnetic resonance image data in method act 40 takes place during a movement (e.g., a continuous movement) of a patient table of the patient positioning device 16 of the magnetic resonance device 11 in a sub-act 40a of the method act 40. Thus, a large volume of the object under investigation may be acquired rapidly. As a consequence thereof, the acquisition of the first magnetic resonance image data in method act 40 takes place from a first recording region, and the acquisition of the second magnetic resonance image data takes place in method act 44 from a second acquisition region. The second recording region is a partial region of the first recording region.

In method act 41, the segmentation unit of the computer unit 24 segments the first magnetic resonance image data into two material classes 41a, 41b, of which a first material class 41a is air, and a second material class 41b is tissue. For the calculation of the B0 map in the method act 42, in method act 47, the respective susceptibility values 47a, 47b of the material classes 41a, 41b are loaded from a database. The calculation of the B0 map in method act 42 is then carried out based on the segmented first magnetic resonance image data, with which the respective susceptibility values 47a, 47b are associated.

In method act 45, before the acquisition of the second magnetic resonance image data, first scan data is acquired by at least one further sensor (not shown) that is different than the magnetic resonance device. Based on the first scan data, in method act 46 using the computer unit 24, a model that describes contours of the object under investigation 15 is determined. This model is used in the segmentation of the first magnetic resonance image data in method act 41. For example, based on the model, patient contours that lie outside the first magnetic resonance image data are determined. Thus, the calculation of the B0 map takes place in the further method act 42, making use of the first scan data, specifically using the model generated from the first scan data.

In the case shown, a movement correction of the calculated B0 map is carried out. For this purpose, in a further method act 48, second scan data is acquired by the further sensor following the acquisition of the second magnetic resonance image data. Based on the second scan data, the model calculated in the further method act 46 is adapted by the computer unit in a further method act 49. For example, the contours of the object under investigation are adapted according to the second scan data. From the B0 map calculated in the further method act 42, making use of the adapted model, an adapted B0 map is determined in a further method act 50. The shim control unit 33 may then calculate adapted shim settings in a further method act 51 based on the adapted B0 map. The shim unit 32 is then controlled by the shim control unit 33, using the adapted shim settings, for the acquisition of third magnetic resonance image data 52 using the image data acquisition unit 34.

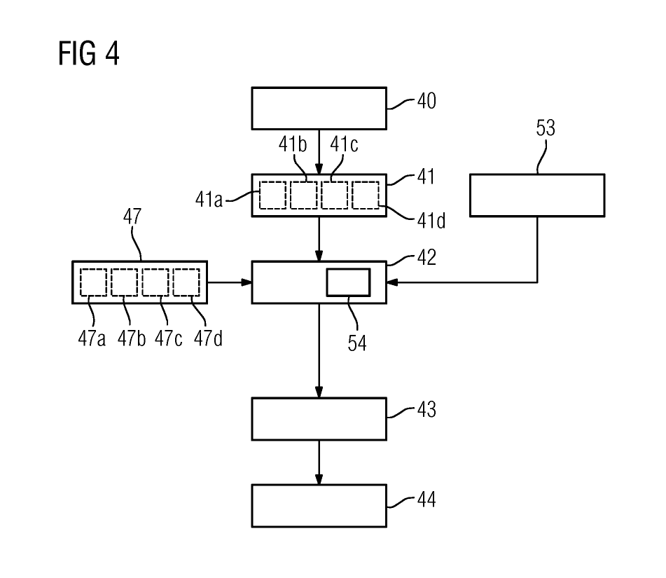

FIG. 4 shows a flow diagram of a third embodiment of a method according to one or more of the present embodiments.

The following description is essentially restricted to the differences from the exemplary embodiment in FIG. 2, where, with regard to method acts that remain the same, reference is made to the description of the exemplary embodiment in FIG. 2. Method acts that are substantially the same are essentially identified with the same reference signs.

The third embodiment of the method shown in FIG. 4 essentially includes the method acts 40, 41, 42, 43, 44 of the first embodiment of the method, as shown in FIG. 2. The method sequence shown in FIG. 4 includes the further method act 47 of the second embodiment of the method in FIG. 3. In addition, the third embodiment of the method shown in FIG. 4 also includes further method acts and sub-acts. An alternative method sequence to that of FIG. 4, which has only part of the additional method acts and/or sub-acts represented in FIG. 2, may also be provided. An alternative method sequence to that of FIG. 4 may also have additional method acts and/or sub-acts.

In the further method act 41, the segmentation unit of the computer unit 24 segments the first magnetic resonance image data into four material classes 41a, 41b, 41c, 41d, of which a first material class 41a is air, a second material class 41b is fatty tissue, a third material class 41c is water-bearing tissue, and a fourth material class 41d is bone tissue. Therefore, the four material classes 41a, 41b, 41c, 41d include three different tissue classes 41b, 41c, 41d. For the calculation of the B0 map in the further method act 42, in a further method act 47, the respective susceptibility values 47a, 47b, 47c, 47d of the material classes 41a, 41b, 41c, 41d are loaded from a database. The calculation of the B0 map in the further method act 42 is then carried out based on the segmented first magnetic resonance image data, with which the respective susceptibility values 47a, 47b, 47c, 47d have been associated. A segmentation of the first magnetic resonance image data deviating from the segmentation shown in FIGS. 3 and 4 into material classes may also be provided.

In the exemplary embodiment shown in FIG. 4, inhomogeneities of the main magnetic field 18 of the magnetic resonance device 11, which are independent of the object under investigation 15, are taken into account in the calculation of the shim settings. This may also take place in addition to the movement correction of the B0 map shown in FIG. 3.

In further method act 53, a calibration scan is carried out before the acquisition of the second magnetic resonance image data by the image data acquisition unit 34 of the magnetic resonance device 11. During the calibration scan, calibration magnetic resonance image data is acquired. With the aid of the calibration magnetic resonance image data, inhomogeneities of the main magnetic field 18 of the magnetic resonance device 11 that are independent of the object under investigation 15 are determined. These inhomogeneities may alternatively or additionally also be set with the aid of known information concerning an embodiment of the main magnet 17. In one embodiment, the inhomogeneities are determined by a simulation.

The inhomogeneities of the main magnetic field that are independent of the object under investigation 15 are taken into account by the calculating unit of the computer unit 24 in a further method act 54 during the calculation of the B0 map in the further method act 42.

The method acts of the method according to one or more of the present embodiments, as shown in FIGS. 2, 3 and 4, are carried out by the magnetic resonance device. For this purpose, the magnetic resonance device includes required software and/or computer programs that are stored in a storage unit of the computer unit and/or the control unit of the magnetic resonance device. The software and/or computer programs include instructions that are configured to carry out the method according to one or more of the present embodiments if the computer program and/or the software in the computer unit and/or the control unit is executed by a processor unit of the computer unit and/or the control unit.

Although the invention has been illustrated and described in detail based on the exemplary embodiments, the invention is not restricted by the examples given. Other variations may be derived therefrom by a person skilled in the art without departing from the protective scope of the invention.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for magnetic resonance imaging of an object under investigation using a magnetic resonance device, the method comprising:
acquiring first magnetic resonance image data of the object under investigation using the magnetic resonance device;
segmenting the first magnetic resonance image data into at least two material classes;
calculating a B0 map based on the segmented first magnetic resonance image data and based on susceptibility values of the at least two material classes;
calculating shim settings based on the calculated B0 map; and
acquiring second magnetic resonance image data of the object under investigation using the magnetic resonance device,
wherein acquiring the second magnetic resonance image data comprises acquiring the second magnetic resonance image data using the calculated shim settings.

2. The method of claim 1, wherein a first of the at least two material classes is air, and a second of the at least two material classes is tissue of the object under investigation.

3. The method of claim 1, wherein the at least two material classes comprise at least two different tissue classes.

4. The method of claim 1, wherein acquiring the first magnetic resonance image data comprises acquiring the first magnetic resonance image data from a first recording region, and
wherein acquiring the second magnetic resonance image data comprises acquiring the second magnetic resonance image data from a second recording region, the second recording region being a partial region of the first recording region.

5. The method of claim 1, wherein acquiring the first magnetic resonance image data comprises acquiring the first magnetic resonance image data during a movement of a patient table of the magnetic resonance device.

6. The method of claim 1, further comprising acquiring first scan data using at least one further sensor different than the magnetic resonance device before the acquisition of the second magnetic resonance image data,
wherein calculating the B0 map comprises using the first scan data.

7. The method of claim 6, wherein following the acquisition of the second magnetic resonance image data, the method further comprises:
acquiring second scan data using the at least one further sensor;
determining an adapted B0 map based on the second scan data and the calculated B0 map;
calculating adapted shim settings based on the adapted B0 map; and
acquiring third magnetic resonance image data from the object under investigation using the magnetic resonance device, and
wherein acquiring the third magnetic resonance image data comprises using the adapted shim settings.

8. The method of claim 6, further comprising determining a model that describes contours of the object under investigation based on the first scan data,
wherein calculating the B0 map comprises using the model.

9. The method of claim 7, wherein the model is adapted based on the second scan data, and
wherein determining the adapted B0 map includes use of the adapted model.

10. The method of claim 1, wherein inhomogeneities of a main magnetic field of the magnetic resonance device that are independent of the object under investigation are taken into account in the calculation of the B0 map.

11. A magnetic resonance device comprising:
an image data acquisition unit configured to:
acquire first magnetic resonance image data of an object under investigation; and
acquire second magnetic resonance image data of the object under investigation;
a shim unit;
a computer unit configured to:
segment the first magnetic resonance image data into at least two material classes; and
calculate a B0 map based on the segmented first magnetic resonance image data and based on susceptibility values of the at least two material classes;
a shim control unit configured to calculate shim settings based on the calculated B0 map,
wherein the acquisition of the second magnetic resonance image data comprises acquisition of the second magnetic resonance image data using the calculated shim settings.

12. The magnetic resonance device of claim 11, wherein a first of the at least two material classes is air, and a second of the at least two material classes is tissue of the object under investigation.

13. The magnetic resonance device of claim 11, wherein the at least two material classes comprise at least two different tissue classes.

14. The magnetic resonance device of claim 11, wherein the acquisition of the first magnetic resonance image data comprises acquisition of the first magnetic resonance image data from a first recording region, and
wherein the acquisition of the second magnetic resonance image data comprises acquisition of the second magnetic resonance image data from a second recording region, the second recording region being a partial region of the first recording region.

15. The magnetic resonance device of claim 11, wherein the acquisition of the first magnetic resonance image data comprises acquisition of the first magnetic resonance image data during a movement of a patient table of the magnetic resonance device.

16. The magnetic resonance device of claim 11, further comprising at least one further sensor configured to acquire first scan data before the acquisition of the second magnetic resonance image data,
wherein the calculation of the B0 map comprises use of the first scan data.

17. The magnetic resonance device of claim 16, wherein following the acquisition of the second magnetic resonance image data:
the at least one further sensor is configured to acquire second scan data;
the computer unit is configured to determine an adapted B0 map based on the second scan data and the calculated B0 map;
the shim control unit is configured to calculate adapted shim settings based on the adapted B0 map; and
the image data acquisition unit is configured to acquire third magnetic resonance image data from the object under investigation, the acquisition of the third magnetic resonance image data comprising use of the adapted shim settings.

18. The magnetic resonance device of claim 16, wherein the computer unit is configured to determine a model that describes contours of the object under investigation based on the first scan data, and
wherein the calculation of the B0 map comprises use of the model.

19. The magnetic resonance device of claim 17, wherein the model is adapted based on the second scan data, and
wherein the determination of the adapted B0 map includes use of the adapted model.

20. The magnetic resonance device of claim 11, wherein inhomogeneities of a main magnetic field of the magnetic resonance device that are independent of the object under investigation are taken into account in the calculation of the B0 map.
